(19) United States
(12) Patent Application Publication
(10) Pub. No.: US 2025/0251535 A1
(43) Pub. Date: Aug. 7, 2025

(54) PASSIVE RETROREFLECTION COUNTERMEASURES BY A DIFFRACTION GRATING AT THE IMAGE PLANE

(71) Applicant: Andrew Boyd, St. Asaph (GB)

(72) Inventor: Andrew Boyd, St. Asaph (GB)

(21) Appl. No.: 19/049,617

(22) Filed: Feb. 10, 2025

Related U.S. Application Data
(63) Continuation of application No. PCT/IB2023/000491, filed on Aug. 17, 2023.
(60) Provisional application No. 63/399,033, filed on Aug. 18, 2022.

(51) Int. Cl. G02B 5/18; H04N 23/51; H04N 23/55; H04N 25/20; H04N 25/76

(52) U.S. Cl. CPC G02B 5/1842; H04N 23/51; H04N 23/55; H04N 25/20; H04N 25/76

(57) ABSTRACT

Designs for mitigating retroreflections in night vision systems are described. The designs described herein use diffraction gratings. A diffraction grating diffracts input light into several beams with different directions. A grating may be configured to transmit input light passing through an aperture stop towards the focal plane array (FPA), and to deviate reflections arising from the FPA in response to the input light outside aperture stop. Deviation of light may be obtained by designing the grating so that the majority of the total diffracted energy is concentrated in a single diffraction order while the energy in the other orders is limited. The diffraction order in which the energy is concentrated may be any diffraction order other than the zeroth order (the un-diffracted order), including for example the first order, the second order, the third order, etc. A grating may be formed as a discrete component or monolithically with the FPA.

### CROSS-REFERENCE TO RELATED APPLICATIONS

This application is a continuation of International Application No. PCT/IB2023/000491, entitled “PASSIVE RETROREFLECTION COUNTERMEASURES BY A DIFFRACTION GRATING AT THE IMAGE PLANE,” filed on Aug. 17, 2023, under Attorney Docket No. E0644.70020WO00, which claims the benefit under 35 U.S.C. § 119(e) of U.S. Provisional Patent Application Ser. No. 63/399,033, entitled “PASSIVE RETROREFLECTION COUNTERMEASURES BY A DIFFRACTION GRATING AT THE IMAGE PLANE,” filed on Aug. 18, 2022, under Attorney Docket No. E0644.70020US00, each of which is hereby incorporated herein by reference in its entirety.

### BACKGROUND

Night vision is a technology that allows individuals to see in low-light or dark environments. It enables the human eye or a device, such as a camera, to amplify available light to make objects visible in conditions where natural vision would be insufficient. The human eye is not particularly effective at seeing in the dark because it relies on visible light, which can be scarce at night. However, night vision technology enhances the available light or captures infrared radiation emitted or reflected by objects, converting it into visible light or an image that the human eye can perceive.

### SUMMARY OF THE DISCLOSURE

Some embodiments relate to an imaging system comprising a housing defining an aperture stop; a focal plane array (FPA); and a diffraction grating disposed between the aperture stop and the FPA, wherein the grating is configured to transmit input light passing through the aperture stop towards the FPA and is further configured to deviate reflections arising from the FPA in response to the input light outside the aperture stop.

In some embodiments, the grating is blazed.

In some embodiments, the grating is a multi-layer blazed grating.

In some embodiments, at least 75% of energy of light diffracted by the blazed grating is focused on one diffraction order other than a zeroth diffraction order.

In some embodiments, less than 5% of energy of light diffracted by the blazed grating is focused on a zeroth diffraction order.

In some embodiments, the imaging system lacks optical components between the grating and the FPA.

In some embodiments, the grating has a spatial periodicity between 20 l/mm and 2000 l/mm.

In some embodiments, the FPA comprises a complementary metal-oxide-semiconductor (CMOS) sensor array.

In some embodiments, the FPA is sensitive to infrared light.

In some embodiments, the grating and the FPA are distinct components.

In some embodiments, the grating and the FPA are co-integrated monolithically.

In some embodiments, the imaging system further comprises one or more lenses between the aperture stop and the grating.

In some embodiments, the grating comprises an antireflection structure.

Some embodiments relate to an imaging system comprising a housing defining an aperture stop configured for passage of input light; and a focal plane array (FPA) patterned with a diffraction grating, wherein the grating is configured to direct reflected input light outside the aperture stop.

In some embodiments, the grating is blazed.

In some embodiments, the grating is a multi-layer blazed grating.

In some embodiments, at least 75% of energy of light diffracted by the blazed grating is focused on one diffraction order other than a zeroth diffraction order.

In some embodiments, less than 5% of energy of light diffracted by the blazed grating is focused on a zeroth diffraction order.

In some embodiments, the diffraction grating is formed as part of an absorption region of the FPA.

In some embodiments, the imaging system further comprises one or more lenses between the aperture stop and the FPA.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1A. illustrates the tapetum lucidum of a cat shining as a result of retroflection of light.

FIG. 1B illustrates a covert observer in a scene under infrared illumination.

FIG. 1C illustrates the covert observer in the scene of FIG. 1B, but in the presence of retroreflection.

FIG. 1D is a schematic diagram illustrating an imaging system in the presence of retroreflection, in accordance with some embodiments.

FIG. 2A is a schematic diagram of an imaging system having a transmissive grating, in accordance with some embodiments.

FIG. 2B is a schematic diagram of an unblazed grating, in accordance with some embodiments.

FIG. 2C is a schematic diagram of a blazed grating, in accordance with some embodiments.

FIG. 3 is a schematic diagram of another imaging system having a transmissive grating, in accordance with some embodiments.

FIG. 4 is a schematic diagram of an imaging system having a focal plane array (FPA) patterned with a diffraction grating, in accordance with some embodiments.

### DETAILED DESCRIPTION

The inventor has recognized and appreciated designs for mitigating retroreflections in night vision systems. Night vision involves the ability to see objects in low-light conditions using a night vision system (e.g., night goggles, image intensifiers, thermographic cameras, etc.). Night vision imaging can be based on visible wavelengths, infrared wavelengths, or both. Humans have poor night vision because the human eye lacks a tapetum lucidum, a layer of tissues lying behind the retina serving as a retroreflector that allows certain animals (e.g., cats) to increase the amount of light available for photoreception.

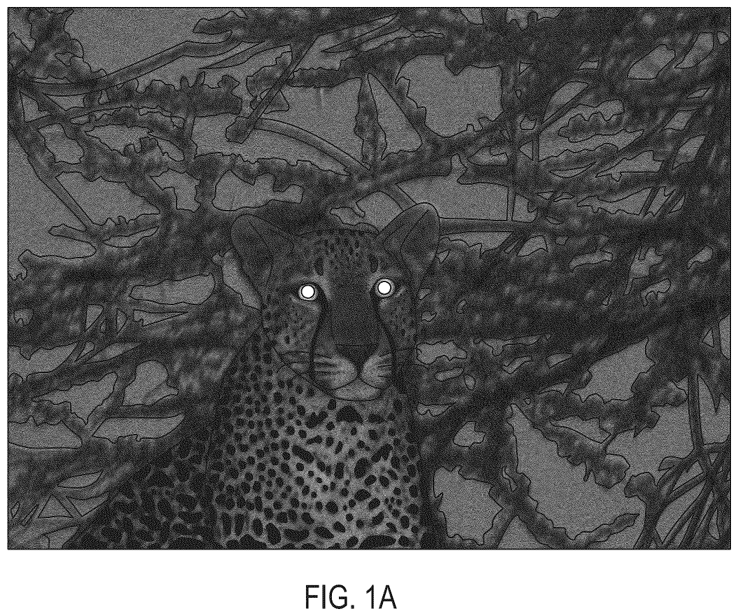

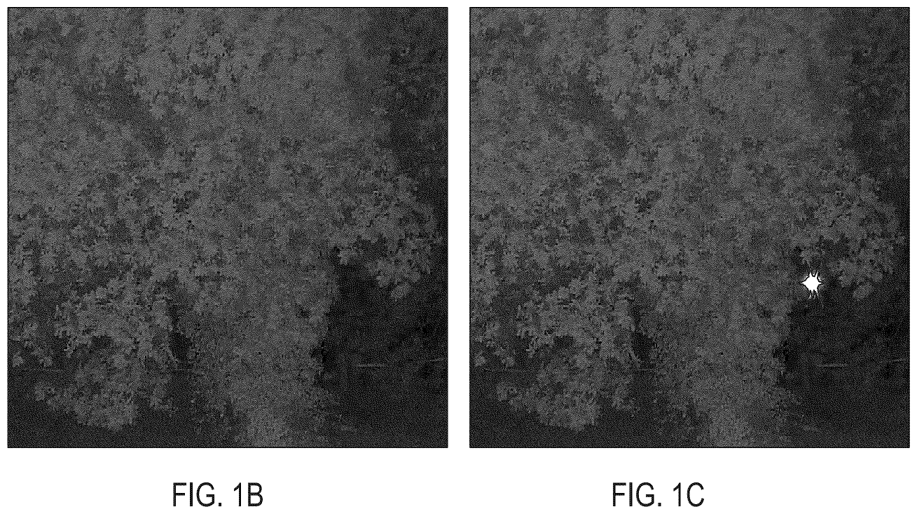

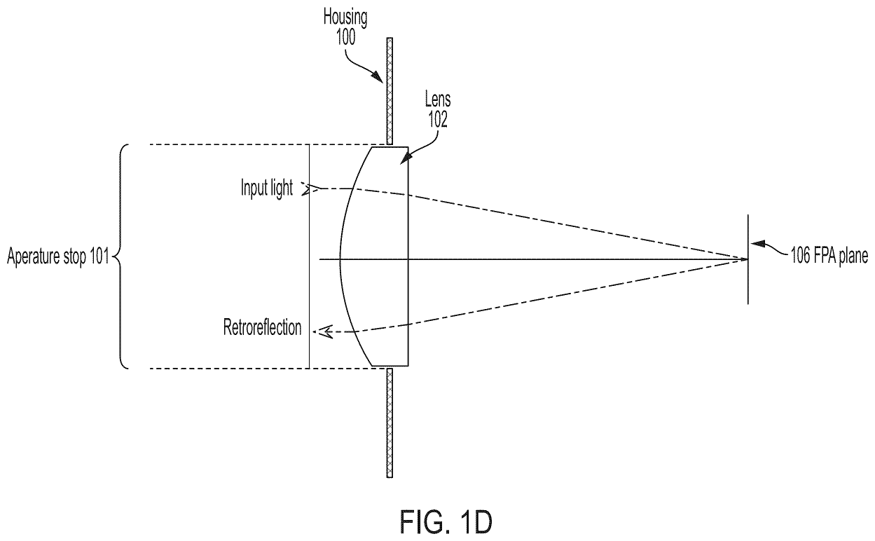

Night vision systems suffer from retroreflection, whereby part of the energy carried by the input light is reflected against the plane of the focal plane array and redirected through the optics back to the illumination source. This is analogous to the eyeshine effect produced by the tapetum lucidum of nocturnal animals, an example of which is depicted in FIG. 1A. In this depiction, the tapetum lucidum of a cat shines as a result of retroflection of light. Retroreflection in night vision systems is undesirable in some circumstances, particularly in military applications. Consider for example use of night vision goggles by military personnel to scan for threats (e.g., people, tanks, etc.). To ensure covert operation, it is important to prevent the night vision system from retroreflecting light back to the illumination source. FIG. 1B illustrates a covert observer in a scene under infrared illumination. This figure represents the ideal scenario—the night vision system does not shine. FIG. 1C illustrates the covert observer in the scene under infrared illumination, but in the presence of retroreflection. The result is that the observer location can be revealed.

FIG. 1D is a schematic diagram illustrating an imaging system (e.g., a night vision system) in the presence of retroreflection. The imaging system includes a housing 100 having an aperture stop 101 defined on it. Aperture stop 101 allows passage of input light. Input light outside aperture stop 101 is blocked by housing 100. Lens 102 focuses the input light on the plane (106) of the focal plane array (FPA). In some embodiments, lens 102 may include an objective having a set of lenses. The FPA includes an array of detectors, sensitive to light in the visible spectrum, in the infrared spectrum, or both. The plane of the FPA is positioned approximately at the focus of lens 102, although in some embodiments the FPA may be positioned slightly off focus. The FPA may be arranged as a metal-oxide-semiconductor (CMOS) sensor array, as a charged-coupled device (CCD), as an array of bolometers, or more generally, in accordance with any architecture that can generate electric signals in response to absorption of electromagnetic radiation. In some embodiments, lens 102 may comprise an antireflection structure (e.g., an antireflection coating) to prevent or at least limit reflections that the lens may otherwise produce. In one example, the antireflection structure may include layers of alternating refractive indices engineered to provide nearly 100% transmittance at the wavelength range of interest. An antireflection structure may further improve the system's ability to prevent retroreflections.

As further shown in FIG. 1D, retroreflection arises as a result of reflection of the input light by the FPA. The reflection can arise due to a variety of effects, including because the refractive index of the material forming the FPA differs from the refractive index of the medium in which the input light propagates (e.g., air). Part of the energy carried by the input light is absorbed by the FPA and part of the energy carried by the input light is reflected. Retroreflection propagating at an angle sufficiently small to pass through aperture stop 101 escapes the imaging system and can be viewed by an observer. As a result, the imaging system can be revealed.

The inventor has recognized and appreciated designs for mitigating retroreflections in imaging systems using diffraction gratings. A diffraction grating diffracts input light into several beams with different directions. The surface of a diffraction grating may include a large number of closely spaced slits or grooves, for example. These slits or grooves act as individual sources of light, which interfere with each other when light passes through them. The interference results in a pattern of bright and dark regions that give rise to a diffraction pattern. Constructive interference is produced only at certain directions which depend on the geometry and composition of the diffraction grating relative to the wavelength of the incident light.

A grating can be reflective or transmissive. In a reflective grating, input light is reflected by the grating, and the reflection includes diffracted beams. In a transmissive grating, input light is transmitted through the grating, and the transmission includes diffracted beams. The angular separation between the diffracted beams and their relative amplitudes depends upon the geometry of the grating, including its periodicity, pattern, etc.

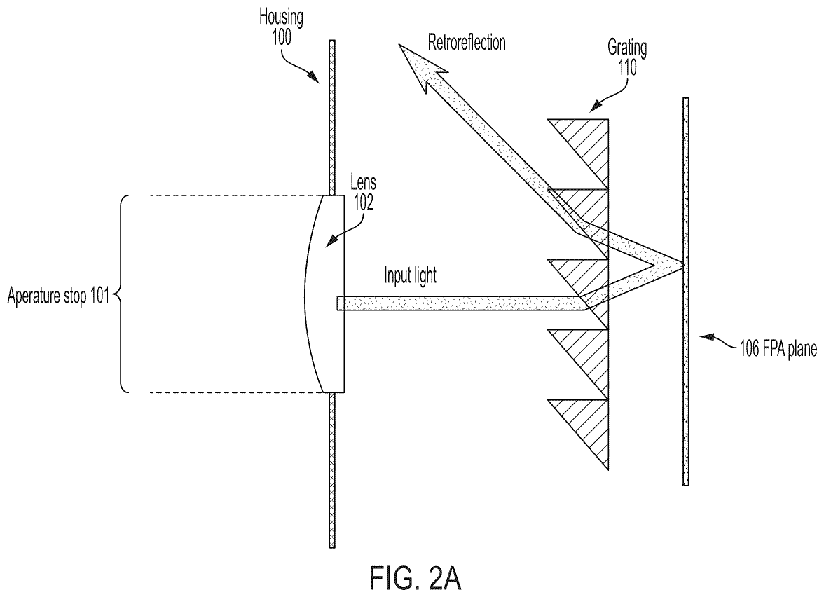

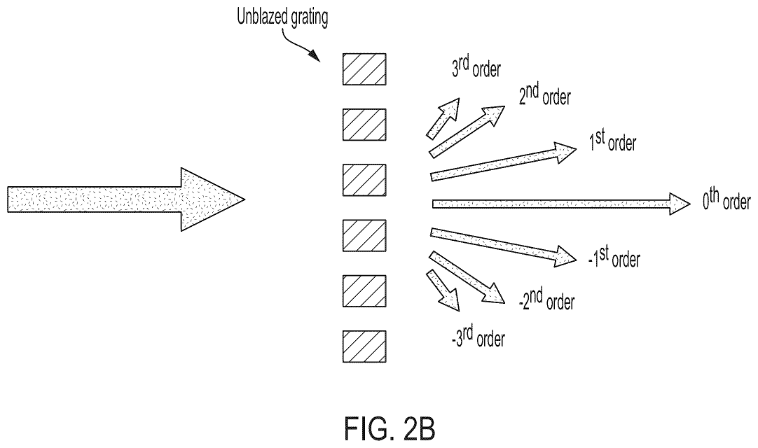

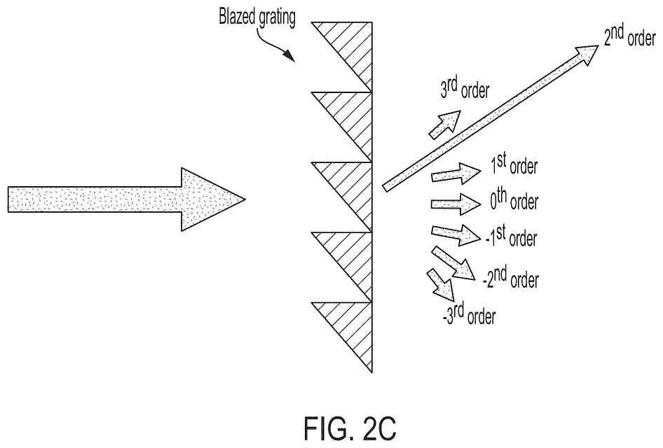

FIG. 2A is a schematic diagram of an imaging system having a transmissive grating. Grating 110 is disposed between aperture stop 101 and FPA plane 106. Grating 110 is configured to transmit input light passing through aperture stop 101 towards the FPA and to deviate reflections arising from the FPA in response to the input light outside aperture stop 101. As shown in FIG. 2A, grating 110 deviates the input light so that the angle of transmission differs from the angle of incidence. Further, the grating deviates the light reflected from the FPA so that the angle of transmission differs from the angle of incidence. Deviation of light may be obtained by designing the grating so that the majority (e.g., more than 50%, more than 75% or more than 90%) of the total diffracted energy is concentrated in a single diffraction order while the energy in the other orders is limited. The diffraction order in which the energy is concentrated may be any diffraction order other than the zeroth order (the un-diffracted order), including for example the first order, the second order, the third order, etc. In some embodiments, this can be accomplished using a blazed grating. Use of a blaze grating avoids spurious diffraction orders coupling light back into the retroreflection path. A blazed grating may have different patterns, including for example a stepped profile. The stepped profile may be in the shape of a triangle or a sawtooth, among other shapes. The blazed grating may be arranged in accordance with a Littrow configuration or an Echelle configuration, among other possible designs. In some embodiments, the grating may be designed so that less than 5% (or less than 3%, or less than 1%) of the light emerging from the grating is in the zeroth order mode (the diffraction order that propagates in a direction that is parallel to the direction of the incident light).

For purposes of illustration, FIGS. 2B and 2C present a comparison between the diffraction pattern produced by an unblazed grating and that produced by a blazed grating, in accordance with some embodiments. For simplicity, these figures illustrate only seven diffraction orders (0^{th}, 1^{st}, 2^{nd}, 3^{rd}, −1^{st}, −2^{nd} and −3^{rd}), but additional orders may arise. The length of the arrow associated with each diffraction order represents the energy associated with that particular order. A longer arrow indicates that the corresponding order has a higher energy than an order represented by a shorter arrow. As shown in FIG. 2B, when light passes through an unblazed grating, although the energy distribution across the various orders is far from being uniform, the grating diffracts the light without focusing it on any particular direction. By contrast, as shown in FIG. 2C, when light passes through a blazed grating, the grating diffracts the light by focusing the majority of the energy in a preferred direction (the 2^{nd} order in this example). For example, more than 50%, more than 75% or more than 90% of the total diffracted energy may be focused on the 2^{nd} order. The preferred order may be selected by engineering the geometry of the blazed grating. In this context, use of blazed gratings provides the ability to focus the majority of the energy on an order that does not pass through the aperture stop upon diffraction.

In some embodiments, the spatial periodicity of the grating may be between 20 l/mm and 2000 l/mm (e.g., between 300 l/mm and 1500 l/mm, between 500 l/mm and 1200 l/mm, between 600 l/mm and 1000 l/mm, between 600 l/mm and 800 l/mm, or 700 l/mm), which in some embodiments may completely clear the aperture stop for all reflected field angle. In some embodiments, the high spatial frequency of the diffraction grating has negligible impact on the quality of the image for a typical image intensified optic (limited to around 70 c/mm, for example).

In some embodiments, the grating may be a multi-layer blazed grating, which has a broadband efficiency, thus enhancing the grating's ability to deflect retroreflections.

In some embodiments, the system lacks optical components between the grating and the FPA.

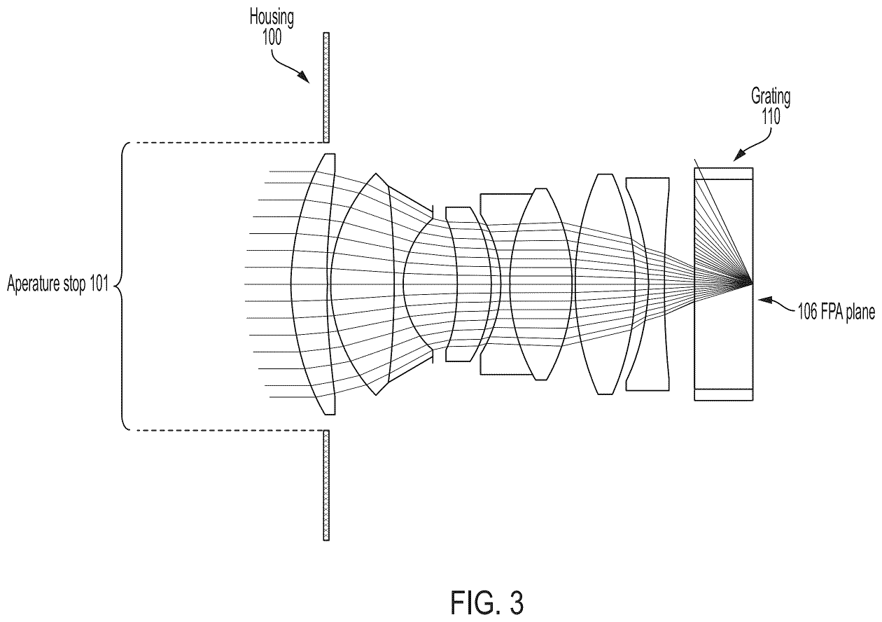

FIG. 3 illustrates a working implementation of the schematic of FIG. 2A. A grating structure is placed at the rear of the tube window. As shown, the retroreflected ray bundle sits outside the nominal ray bundle and, as a result, does not proceed through the aperture stop unless aided by another reflection event. This particular implementation further includes a series of singlet and doublet lenses with a variety of convex and concave surfaces, although the solutions described herein are not limited to any particular optical system.

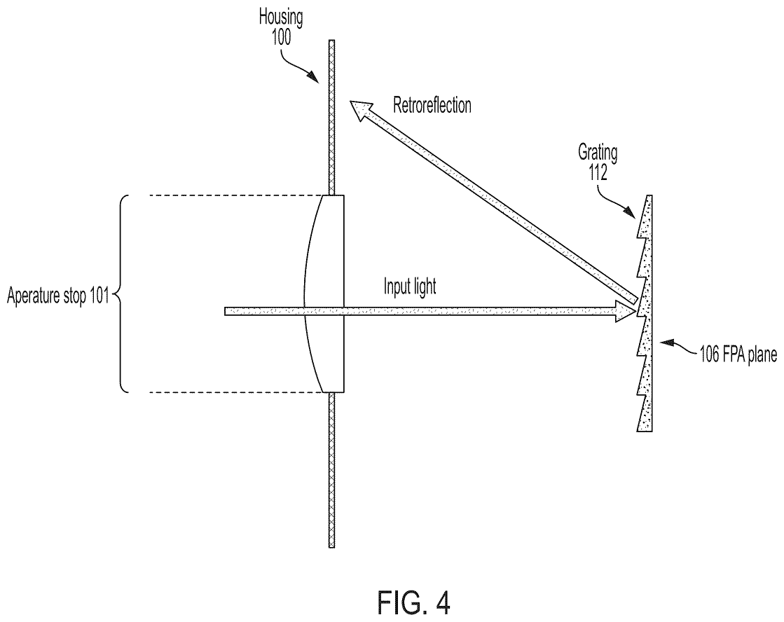

In the examples of FIGS. 2A and 3, the grating is formed as a discrete component, distinct from the FPA. In the example of FIG. 4, a grating 114 is formed monolithically with the FPA and operates as a reflective grating. This may be accomplished for example by etching the outer surface of the FPA (or by etching the absorption region of the FPA) with a periodic pattern shaped to provide diffraction orders. As in the example of FIG. 2A, grating 112 may be blazed, thereby concentrating the majority of the total diffracted energy into a single diffraction order (other than the zeroth order). In some embodiments, the grating may be designed so that less than 5% (or less than 3%, or less than 1%) of the light emerging from the grating is in the zeroth order mode. The grating may be formed as part of the region of the FPA that absorbs light. In that respect, the grating may be viewed as partially absorptive and partially reflective. Monolithically integrating the grating with the FPA may reduce the overall footprint of the device relative to having distinct components as in the example of FIG. 2A.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

The definitions, as defined and used herein, should be understood to control over dictionary definitions, definitions in documents incorporated by reference and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some case and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately,” “substantially,” and “about” may be used to mean within ±10% of a target value in some embodiments. The terms “approximately,” “substantially,” and “about” may include the target value.

Use of ordinal terms such as “first,” “second,” “third,” etc., in the claims to modify a claim element does not by itself connotate any priority, precedence, or order of one claim element over another or the temporal order in which acts of a method are performed, but are used merely as labels to distinguish one claim element having a certain name from another claim element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

What is claimed is:

1. An imaging system comprising:
a housing defining an aperture stop;
a focal plane array (FPA); and
a diffraction grating disposed between the aperture stop and the FPA, wherein the grating is configured to transmit input light passing through the aperture stop towards the FPA and is further configured to deviate reflections arising from the FPA in response to the input light outside the aperture stop.

2. The imaging system of claim 1, wherein the grating is blazed.

3. The imaging system of claim 2, wherein the grating is a multi-layer blazed grating.

4. The imaging system of claim 2, wherein at least 75% of energy of light diffracted by the blazed grating is focused on one diffraction order other than a zeroth diffraction order.

5. The imaging system of claim 2, wherein less than 5% of energy of light diffracted by the blazed grating is focused on a zeroth diffraction order.

6. The imaging system of claim 1, wherein the imaging system lacks optical components between the grating and the FPA.

7. The imaging system of claim 1, wherein the grating has a spatial periodicity between 20 l/mm and 2000 l/mm.

8. The imaging system of claim 1, wherein the FPA comprises a complementary metal-oxide-semiconductor (CMOS) sensor array.

9. The imaging system of claim 1, wherein the FPA is sensitive to infrared light.

10. The imaging system of claim 1, wherein the grating and the FPA are distinct components.

11. The imaging system of claim 1, wherein the grating and the FPA are co-integrated monolithically.

12. The imaging system of claim 1, further comprising one or more lenses between the aperture stop and the grating.

13. The imaging system of claim 1, wherein the grating comprises an antireflection structure.

14. An imaging system comprising:
a housing defining an aperture stop configured for passage of input light; and
a focal plane array (FPA) patterned with a diffraction grating, wherein the grating is configured to direct reflected input light outside the aperture stop.

15. The imaging system of claim 14, wherein the grating is blazed.

16. The imaging system of claim 15, wherein the grating is a multi-layer blazed grating.

17. The imaging system of claim 15, wherein at least 75% of energy of light diffracted by the blazed grating is focused on one diffraction order other than a zeroth diffraction order.

18. The imaging system of claim 15, wherein less than 5% of energy of light diffracted by the blazed grating is focused on a zeroth diffraction order.

19. The imaging system of claim 15, wherein the diffraction grating is formed as part of an absorption region of the FPA.

20. The imaging system of claim 14, further comprising one or more lenses between the aperture stop and the FPA.
